(19) United States
(12) Patent Application Publication
(10) Pub. No.: US 2007/0153610 A1
(43) Pub. Date: Jul. 5, 2007

(54) Dynamic body bias with bias boost

(75) Inventors: Fatih Hamzaoglu, Hillsboro, OR (US); Kevin Zhang, Portland, OR (US); Yih Wang, Portland, OR (US)

Correspondence Address: INTEL CORPORATION;c/o INTELLEVATE, LLC, P.O. BOX 52050, MINNEAPOLIS, MN, 55402, US

(73) Assignee: INTEL CORPORATION

(21) Appl. No.: 11/323,361

(22) Filed: Dec. 29, 2005

(51) Int. Cl. G11C 5/14

(52) U.S. Cl. 365/226

(57) ABSTRACT

For one disclosed embodiment, circuitry may bias one or more wells of a substrate from a first state to a second state. Bias by the circuitry of one or more wells of the substrate to the second state may be boosted. Other embodiments are also disclosed.

### FIELD

Embodiments described herein generally relate to integrated circuits.

### BACKGROUND

One technique to improve the speed of a circuit is to scale the threshold voltage (Vt) of transistors. Reducing threshold voltage, however, can increase sub-threshold current leakage and therefore increase power consumption. Dynamic forward body biasing (FBB) may be used to reduce threshold voltage of a field effect transistor (FET) only during an active mode to improve the strength of the FET while also helping to reduce or minimize any increased leakage during, for example, a standby mode.

### BRIEF DESCRIPTION OF THE DRAWINGS

Embodiments are illustrated by way of example and not limitation in the figures of the accompanying drawings, in which like references indicate similar elements and in which:

FIG. 1 illustrates, for one embodiment, a block diagram of an integrated circuit comprising circuitry to dynamically bias one or more wells of a substrate with a bias boost;

FIG. 2 illustrates, for one embodiment, a flow diagram to dynamically bias one or more wells of a substrate with a bias boost;

FIG. 3 illustrates, for one embodiment, a block diagram of example circuitry for dynamic bias circuitry and boost circuitry of FIG. 1;

FIG. 4 illustrates, for one embodiment, example circuitry for dynamic bias circuitry and boost circuitry of FIG. 1 to bias one or more n-type wells;

FIG. 5 illustrates, for one embodiment, example circuitry for dynamic bias circuitry and boost circuitry of FIG. 1 to bias one or more p-type wells;

FIG. 6 illustrates, for one embodiment, an example timing diagram for the example circuitry of FIGS. 4 and 5; and

FIG. 7 illustrates, for one embodiment, a block diagram of an example system comprising a processor having a cache memory including circuitry to dynamically bias one or more wells of a substrate with a bias boost.

The figures of the drawings are not necessarily drawn to scale.

### DETAILED DESCRIPTION

The following detailed description sets forth example embodiments of apparatuses, methods, and systems relating to dynamic body bias with a bias boost. Features, such as structure(s), function(s), and/or characteristic(s) for example, are described with reference to one embodiment as a matter of convenience; various embodiments may be implemented with any suitable one or more described features.

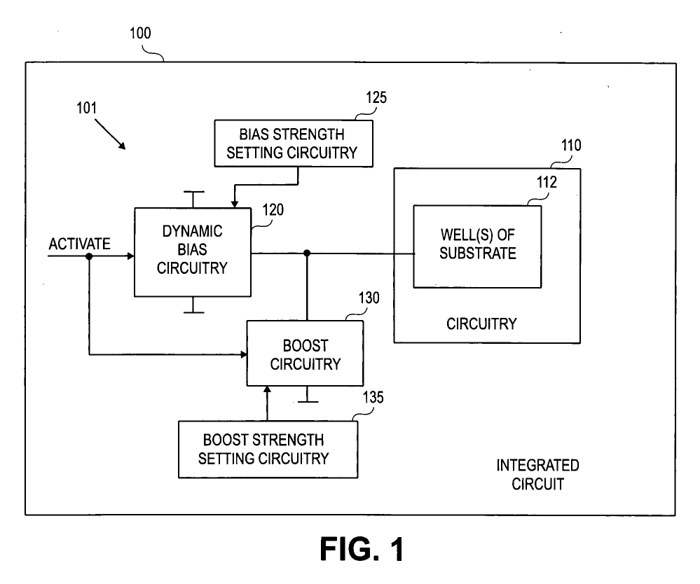

FIG. 1 illustrates, for one embodiment, an integrated circuit 100 comprising circuitry 101 to dynamically bias one or more wells 112 of a substrate with a bias boost. Using a bias boost for one embodiment may help bias well(s) 112 faster. Using a bias boost for one embodiment may help bias well(s) 112 faster to help allow circuitry 110 including well(s) 112 to be used sooner following biasing of well(s) 112, helping to speed performance. Using a bias boost for one embodiment may help bias well(s) 112 faster to help delay having to initiate biasing of well(s) 112 prior to use of circuitry 110.

Circuitry 101 for one embodiment, as illustrated in FIG. 1, may comprise dynamic bias circuitry 120 and boost circuitry 130. Dynamic bias circuitry 120 for one embodiment may bias one or more wells 112 from a first state to a second state. Boost circuitry 130 for one embodiment may boost bias by dynamic bias circuitry 120 of well(s) 112 to the second state.

The first state for one embodiment may correspond to a non-biased state, and the second state for one embodiment may correspond to a biased state. The second state for one embodiment may correspond to a forward biased state to reduce a threshold voltage (Vt) of one or more devices, such as a transistor for example, of circuitry 110 to help improve the speed of circuitry 110.

Circuitry 101 for one embodiment may be activated to bias well(s) 112 to the second state for circuitry 110 in an active mode. Circuitry 101 for one embodiment may be activated to initiate and/or complete biasing prior to placement of circuitry 110 in an active mode. Circuitry 101 for one embodiment may be activated to initiate biasing of well(s) 112 in response to or upon placement of circuitry 110 in an active mode.

Circuitry 101 for one embodiment may be deactivated to return well(s) 112 to the first state for circuitry 110 in another mode, such as a standby mode for example. Circuitry 101 for one embodiment may be deactivated to initiate returning well(s) 112 to the first state prior to, in response to, or upon placement of circuitry 110 in another mode.

Circuitry 101 for one embodiment, as illustrated in FIG. 1, may be selectively activated or deactivated in response to one or more activate signals. Any suitable signal(s) may be generated in any suitable manner to activate and deactivate circuitry 101. Dynamic bias circuitry 120 for one embodiment may be coupled to receive one or more activate signals to bias well(s) 112 in response to such activate signal(s). Boost circuitry 130 for one embodiment may be coupled to receive one or more activate signals to boost bias by dynamic bias circuitry 120 in response to such activate signal(s).

Dynamic bias circuitry 120 for one embodiment may optionally have a programmable bias strength. Dynamic bias circuitry 120 for one embodiment, as illustrated in FIG. 1, may be coupled to receive one or more bias strength setting signals from bias strength setting circuitry 125. Bias strength setting circuitry 125 for one embodiment may include one or more registers that may be programmed to store desired bias strength setting signals. The bias strength may be programmed, for example, to help bias well(s) 112 to a desired voltage level. The bias strength may be programmed, for example, to help compensate for process, voltage, and/or temperature (PVT) variations.

Boost circuitry 130 for one embodiment may optionally have a programmable boost strength. Boost circuitry 130 for one embodiment, as illustrated in FIG. 1, may be coupled to receive one or more boost strength setting signals from boost strength setting circuitry 135. Boost strength setting circuitry 135 for one embodiment may include one or more registers that may be programmed to store desired boost strength setting signals. The boost strength may be programmed, for example, to help boost bias of well(s) 112 to the second state at a desired rate.

Although illustrated as already coupled to bias well(s) 112, circuitry 101 for one embodiment may be selectively coupled by any suitable switching circuitry, such as a multiplexer for example, to bias well(s) 112. Circuitry 101 for one embodiment may also be selectively coupled by such switching circuitry to bias one or more other wells of the substrate. Integrated circuit 100 for one embodiment may also comprise other circuitry similar to circuitry 101 to dynamically bias one or more other wells of the substrate with a bias boost.

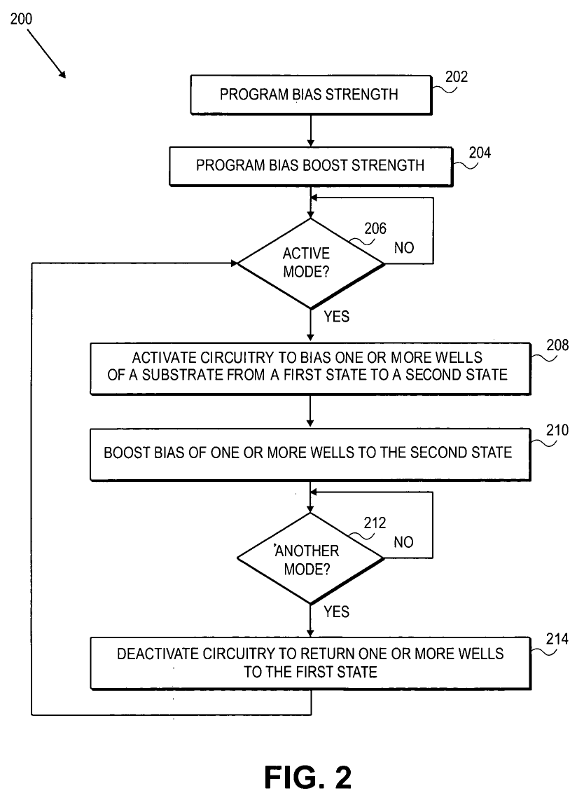

FIG. 2 illustrates, for one embodiment, a flow diagram 200 to dynamically bias one or more wells 112 with a bias boost.

For block 202 of FIG. 2, a strength at which well(s) 112 are to be biased may optionally be programmed. Such strength for one embodiment may be programmed using bias strength setting circuitry 125. For block 204, a strength at which bias is to be boosted may optionally be programmed. Such strength for one embodiment may be programmed using boost strength setting circuitry 135.

If and when circuitry 110 including well(s) 112 is about to be placed, is being placed, or has been placed for block 206 in an active mode, dynamic bias circuitry 120 may be activated for block 208 to bias well(s) 112 from a first state to a second state, and bias of well(s) 112 by dynamic bias circuitry 120 to the second state may be boosted for block 210. Such bias for one embodiment may be boosted using boost circuitry 130.

If and when circuitry 110 including well(s) 112 is about to be placed, is being placed, or has been placed for block 212 in another mode, such as a standby mode for example, dynamic bias circuitry 120 may be deactivated for block 214 to return well(s) 112 to the first state.

Operations for blocks 206-214 for one embodiment may be repeated for subsequent placement(s) of circuitry 110 in the active mode.

### EXAMPLE DYNAMIC BIAS AND BOOST CIRCUITRY

Dynamic bias circuitry 120 and boost circuitry 130 may include any suitable circuitry to dynamically bias one or more wells 112 of any suitable type with a bias boost.

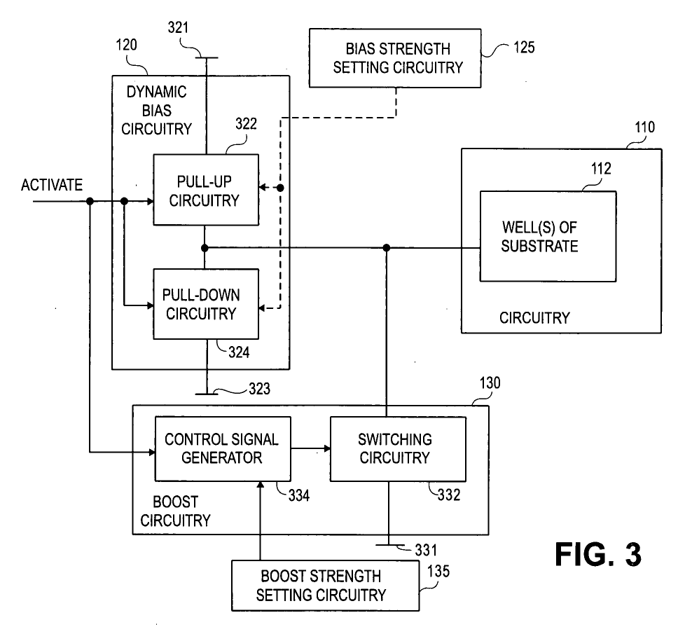

Dynamic bias circuitry 120 for one embodiment, as illustrated in FIG. 3, may include pull-up circuitry 322 to couple well(s) 112 to one or more supply nodes, such as a supply node 321 for example, and may include pull-down circuitry 324 to couple well(s) 112 to one or more supply nodes, such as a supply node 323 for example. Supply node(s) coupled by pull-up circuitry 322 may be at a higher supply voltage relative to supply node(s) coupled by pull-down circuitry. For one embodiment, supply node(s) coupled by pull-down circuitry 324 may be at ground, for example.

Pull-up circuitry 322 for one embodiment may be coupled to receive one or more activate signals and may be activated in response to one or more activate signals to help increase a voltage level of well(s) 112. Pull-up circuitry 322 for one embodiment may be activated to help bias well(s) 112 to a second state. Pull-up circuitry 322 for one embodiment may be activated to help return well(s) 112 to a first state. Pull-up circuitry 322 for one embodiment may be deactivated when pull-down circuitry 324 is activated.

Pull-up circuitry 322 may include any suitable circuitry. Pull-up circuitry 322 for one embodiment may include one or more transistors to selectively couple well(s) 112 to or decouple well(s) 112 from one or more supply nodes. Pull-up circuitry 322 for one embodiment may include multiple transistors coupled in parallel to selectively couple well(s) 112 to or decouple well(s) 112 from a supply node. For one embodiment, one or more transistors may be selectively activated in response to one or more activate signals to couple well(s) 112 to a supply node.

Pull-up circuitry 322 for one embodiment may include a variable resistor coupled between well(s) 112 and a supply node. Such a variable resistor for one embodiment may be implemented using multiple transistors coupled in parallel to be selectively activated in response to one or more bias strength setting signals from bias strength setting circuitry 125 to couple well(s) 112 to a supply node to help set a bias strength for pull-up circuitry 322. Pull-up circuitry 322 may therefore couple one or more wells 112 to a supply node when pull-up circuitry 322 is deactivated.

Pull-up circuitry 322 may include transistor(s) of any suitable type, such as one or more suitable field effect transistors (FETs) for example, and of any suitable size.

Pull-down circuitry 324 for one embodiment may be coupled to receive one or more activate signals and may be activated in response to one or more activate signals to help decrease a voltage level of well(s) 112. Pull-down circuitry 324 for one embodiment may be activated to help bias well(s) 112 to a second state. Pull-down circuitry 324 for one embodiment may be activated to return well(s) 112 to a first state. Pull-down circuitry 324 for one embodiment may be deactivated when pull-up circuitry 322 is activated.

Pull-down circuitry 324 may include any suitable circuitry. Pull-down circuitry 324 for one embodiment may include one or more transistors to selectively couple well(s) 112 to or decouple well(s) 112 from one or more supply nodes. Pull-down circuitry 324 for one embodiment may include multiple transistors coupled in parallel to selectively couple well(s) 112 to or decouple well(s) 112 from a supply node. For one embodiment, one or more transistors may be selectively activated in response to one or more activate signals to couple well(s) 112 to a supply node.

Pull-down circuitry 324 for one embodiment may include a variable resistor coupled between well(s) 112 and a supply node. Such a variable resistor for one embodiment may be implemented using multiple transistors coupled in parallel to be selectively activated in response to one or more bias strength setting signals from bias strength setting circuitry 125 to couple well(s) 112 to a supply node to help set a bias strength for pull-down circuitry 324. Pull-down circuitry 324 may therefore continue to couple one or more wells 112 to a supply node when pull-down circuitry 324 is deactivated.

Pull-down circuitry 324 may include transistor(s) of any suitable type, such as one or more suitable field effect transistors (FETs) for example, and of any suitable size.

Boost circuitry 130 for one embodiment, as illustrated in FIG. 3, may include switching circuitry 332 to selectively couple well(s) 112 to or decouple well(s) 112 from one or more supply nodes, such as a supply node 331 for example. Boost circuitry 130 for one embodiment may also include a control signal generator 334 to generate one or more control signals. Switching circuitry 332 for one embodiment may be coupled to receive one or more control signals and may be activated in response to one or more control signals to couple well(s) 112 to a supply node.

Control signal generator 334 for one embodiment may be coupled to receive one or more activate signals and may be activated in response to one or more activate signals to generate one or more control signals to activate switching circuitry 332. For one embodiment where pull-up circuitry 322 and/or pull-down circuitry 324 may be activated in response to one or more activate signals to bias well(s) 112 to a second state, switching circuitry 332 for one embodiment may then also be activated to couple well(s) 112 to a supply node at a suitable voltage to boost bias of well(s) 112 to the second state. For one embodiment where pull-up circuitry 322 may help increase a voltage level of well(s) 112 to bias well(s) 112 to the second state, switching circuitry 332 for one embodiment may be activated to couple well(s) 112 to a supply node at a higher voltage. For one embodiment where pull-down circuitry 324 may help decrease a voltage level of well(s) 112 to bias well(s) 112 to the second state, switching circuitry 332 for one embodiment may be activated to couple well(s) 112 to a supply node at a lower voltage, such as ground for example.

Switching circuitry 332 for one embodiment may be activated to couple well(s) 112 to a supply node temporarily relative to the amount of time well(s) 112 are biased to the second state by pull-up circuitry 322 and/or pull-down circuitry 324. In this manner, boost circuitry 130 for one embodiment may help bias well(s) 112 to the second state faster and then allow dynamic bias circuitry 120 to maintain well(s) 112 in the second state. Boost circuitry 130 for one embodiment may help bias well(s) 112 to the second state faster as compared to the speed with which dynamic bias circuitry 120 alone would have taken when similarly activated to bias well(s) 112 to the second state.

Switching circuitry 332 for one embodiment may be activated to couple weli(s) 112 to a supply node until a voltage level of well(s) 112 approaches or enters the second state. Switching circuitry 332 for one embodiment may be activated to couple well(s) 112 to a supply node until a voltage level of well(s) 112 approaches, substantially meets, or exceeds a threshold voltage.

Control signal generator 334 may include any suitable circuitry to generate any suitable one or more control signals. Control signal generator 334 for one embodiment may include a pulse generator to generate one or more pulsed control signals, and switching circuitry 332 for one embodiment may be activated to couple well(s) 112 to a supply node for an amount of time based on a width or duration of one or more pulsed control signals. Such a pulse generator for one embodiment may be programmable to set the width or duration of one or more generated pulsed control signals in response to one or more boost strength setting signals from boost strength setting circuitry 135.

Switching circuitry 332 may include any suitable circuitry. Switching circuitry 332 for one embodiment may include one or more transistors to selectively couple well(s) 112 to or decouple well(s) 112 from one or more supply nodes. Switching circuitry 332 for one embodiment may include multiple transistors coupled in parallel to selectively couple well(s) 112 to or decouple well(s) 112 from a supply node. For one embodiment, one or more transistors may be selectively activated in response to one or more control signals to couple well(s) 112 to a supply node.

### EXAMPLE CIRCUITRY TO BIAS N-TYPE WELL(S)

Dynamic bias circuitry 120 and boost circuitry 130 for one embodiment may include any suitable circuitry to dynamically bias one or more n-type wells, for example, with a bias boost. Dynamic bias circuitry 120 and boost circuitry 130 for one embodiment may decrease a voltage level at such well(s) to forward bias such well(s) from a first state to a second state with a bias boost. Dynamic bias circuitry 120 for one embodiment may then increase a voltage level at such well(s) to return such well(s) to a first state.

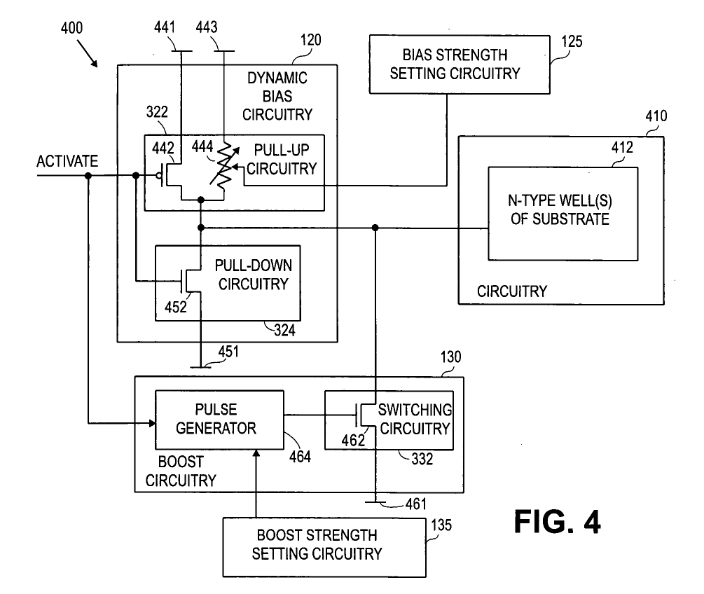

FIG. 4 illustrates, for one embodiment, example circuitry 400 for dynamic bias circuitry 120 and boost circuitry 130 to bias one or more n-type wells 412 for circuitry 410. Circuitry 410 for one embodiment may include one or more devices implemented using p-channel metal oxide semiconductor (PMOS) technology, for example.

As illustrated in FIG. 4, dynamic bias circuitry 120 for one embodiment may include pull-up circuitry 322 including a pull-up transistor 442 coupled between n-type well(s) 412 and a supply node 441 and including a variable resistor 444 coupled between n-type well(s) 412 and a supply node 443. Variable resistor 444 for one embodiment may be implemented using multiple transistors coupled in parallel to be selectively activated in response to one or more bias strength setting signals from bias strength setting circuitry 125.

Dynamic bias circuitry 120 for one embodiment may include pull-down circuitry 324 including a pull-down transistor 452 coupled between n-type well(s) 412 and a supply node 451.

Boost circuitry 130 for one embodiment may include switching circuitry 332 including a pull-down transistor 462 coupled between n-type well(s) 412 and a supply node 461. Boost circuitry 130 for one embodiment may also include a pulse generator 464 coupled to generate a pulse control signal to activate pull-down transistor 462. Pulse generator 464 for one embodiment may be programmable to set a width or duration of a generated pulse control signal in response to one or more boost strength setting signals from boost strength setting circuitry 135. Pulse generator 464 generally corresponds to control signal generator 334 of FIG. 3.

Pull-up transistor 442, any transistors of variable resistor 444, and pull-down transistors 452 and 462 may be of any suitable type and size. As illustrated in FIG. 4, pull-up transistor 442 for one embodiment may be a p-channel field effect transistor (pFET), and pull-down transistors 452 and 462 for one embodiment may be n-channel field effect transistors (nFETs). Variable resistor 444 for one embodiment may be implemented using any suitable number of nFETs or pFETs.

Supply nodes 441 and 443 for one embodiment may be at a voltage higher than that at supply nodes 451 and 461. Supply nodes 441 and 443 may or may not be the same node and/or at the same voltage. Supply nodes 451 and 461 may or may not be the same node and/or at the same voltage.

For one embodiment, pull-up transistor 442 may be activated in response to a deasserted activate signal to couple n-type well(s) 412 to supply node 441, and pull-down transistor 452 may be deactivated in response to the deasserted activate signal to decouple n-type well(s) 412 from supply node 451. One or more n-type wells 412 may then be placed in a first state at a voltage level based at least partially on the strengths of pull-up transistor 442 and variable resistor 444 and the voltage at supply nodes 441 and 443.

Pull-up transistor 442 may be deactivated in response to an asserted activate signal to decouple n-type well(s) 412 from supply node 441, and pull-down transistor 452 may be activated in response to the asserted activate signal to couple n-type well(s) 412 to supply node 451. Pull-down transistor 452 may initially decrease a voltage level of n-type well(s) 412 to place n-type well(s) 412 in a second state at a voltage level based at least partially on the strengths of pull-down transistor 452 and variable resistor 444 and the voltage at supply nodes 443 and 451.

To help boost placement of n-type well(s) 412 in the second state, pulse generator 464 may be activated in response to the asserted activate signal to generate a pulse control signal to temporarily activate pull-down transistor 462 to couple n-type well(s) 412 to supply node 461. The rate at which n-type well(s) 412 may be boosted to the second state may be based at least partially on the strengths of pull-down transistors 452 and 462 and variable resistor 444 and the voltage at supply nodes 443, 451, and 461. Pull-down transistor 462 for one embodiment may have a relatively large size relative to that of pull-down transistor 452 to help boost bias of n-type well(s) faster. Because pull-down transistor 462 for one embodiment may be activated temporarily to help pull-down transistor 452 place n-type well(s) 412 in the second state, pull-down transistor 452 for one embodiment may be sized smaller to help reduce or minimize direct current (DC) power consumption by circuitry 400.

For one embodiment where variable resistor 444 may be implemented using any suitable number of n-channel field effect transistors (nFETs), such nFETs for one embodiment may be activated after a threshold voltage (Vtn) due to forward biasing of n-type well(s) 412 is developed. Using such nFETs for one embodiment may then help allow pull-down transistors 452 and 462 to boost bias of n-type well(s) 412 to the second state faster.

To return n-type well(s) 412 to the first state, pull-up transistor 442 may be activated in response to a deasserted activate signal and pull-down transistor 452 may be deactivated in response to the deasserted activate signal to increase a voltage level of n-type well(s) 412. For one embodiment where return of n-type well(s) 412 to the first state is less time critical, pull-up transistor 442 may be sized smaller to help reduce or minimize direct current (DC) power consumption by circuitry 400.

### EXAMPLE CIRCUITRY TO BIAS P-TYPE WELL(S)

Dynamic bias circuitry 120 and boost circuitry 130 for one embodiment may include any suitable circuitry to dynamically bias one or more p-type wells, for example, with a bias boost. Dynamic bias circuitry 120 and boost circuitry 130 for one embodiment may increase a voltage level at such well(s) to forward bias such well(s) from a first state to a second state with a bias boost. Dynamic bias circuitry 120 for one embodiment may then decrease a voltage level at such well(s) to return such well(s) to a first state.

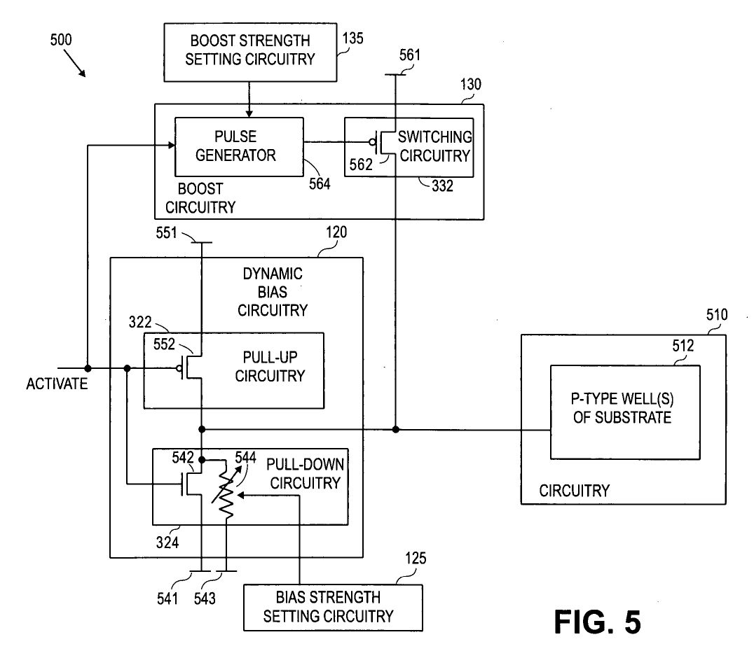

FIG. 5 illustrates, for one embodiment, example circuitry 500 for dynamic bias circuitry 120 and boost circuitry 130 to bias one or more p-type wells 512 for circuitry 510. Circuitry 510 for one embodiment may include one or more devices implemented using n-channel metal oxide semiconductor (NMOS) technology, for example.

As illustrated in FIG. 5, dynamic bias circuitry 120 for one embodiment may include pull-down circuitry 324 including a pull-down transistor 542 coupled between p-type well(s) 512 and a supply node 541 and including a variable resistor 544 coupled between p-type well(s) 512 and a supply node 543. Variable resistor 544 for one embodiment may be implemented using multiple transistors coupled in parallel to be selectively activated in response to one or more bias strength setting signals from bias strength setting circuitry 125.

Dynamic bias circuitry 120 for one embodiment may include pull-up circuitry 322 including a pull-up transistor 552 coupled between p-type well(s) 512 and a supply node 551.

Boost circuitry 130 for one embodiment may include switching circuitry 332 including a pull-up transistor 562 coupled between p-type well(s) 512 and a supply node 561. Boost circuitry 130 for one embodiment may also include a pulse generator 564 coupled to generate a pulse control signal to activate pull-up transistor 562. Pulse generator 564 for one embodiment may be programmable to set a width or duration of a generated pulse control signal in response to one or more boost strength setting signals from boost strength setting circuitry 135. Pulse generator 564 generally corresponds to control signal generator 334 of FIG. 3.

Pull-down transistor 542, any transistors of variable resistor 544, and pull-up transistors 552 and 562 may be of any suitable type and size. As illustrated in FIG. 5, pull-down transistor 542 for one embodiment may be an n-channel field effect transistor (nFET), and pull-up transistors 552 and 562 for one embodiment may be p-channel field effect transistors (pFETs). Variable resistor 544 for one embodiment may be implemented using any suitable number of pFETs or nFETs.

Supply nodes 541 and 543 for one embodiment may be at a voltage lower than that at supply nodes 551 and 561. Supply nodes 541 and 543 may or may not be the same node and/or at the same voltage. Supply nodes 551 and 561 may or may not be the same node and/or at the same voltage.

For one embodiment, pull-down transistor 542 may be activated in response to a deasserted activate signal to couple p-type well(s) 512 to supply node 541, and pull-up transistor 552 may be deactivated in response to the deasserted activate signal to decouple p-type well(s) 512 from supply node 551. One or more p-type wells 512 may then be placed in a first state at a voltage level based at least partially on the strengths of pull-down transistor 542 and variable resistor 544 and the voltage at supply nodes 541 and 543.

Pull-down transistor 542 may be deactivated in response to an asserted activate signal to decouple p-type well(s) 512 from supply node 541, and pull-up transistor 552 may be activated in response to the asserted activate signal to couple p-type well(s) 512 to supply node 551. Pull-up transistor 552 may initially increase a voltage level of p-type well(s) 512 to place p-type well(s) 512 in a second state at a voltage level based at least partially on the strengths of pull-up transistor 552 and variable resistor 544 and the voltage at supply nodes 543 and 551.

To help boost placement of p-type well(s) 512 in the second state, pulse generator 564 may be activated in response to the asserted activate signal to generate a pulse control signal to temporarily activate pull-up transistor 562 to couple p-type well(s) 512 to supply node 561. The rate at which p-type well(s) 512 may be boosted to the second state may be based at least partially on the strengths of pull-up transistors 552 and 562 and variable resistor 544 and the voltage at supply nodes 543, 551, and 561. Pull-Lp transistor 562 for one embodiment may have a relatively large size relative to that of pull-up transistor 552 to help boost bias of p-type well(s) faster. Because pull-up transistor 562 for one embodiment may be activated temporarily to help pull-up transistor 552 place p-type well(s) 512 in the second state, pull-up transistor 552 for one embodiment may be sized smaller to help reduce or minimize direct current (DC) power consumption by circuitry 500.

For one embodiment where variable resistor 544 may be implemented using any suitable number of p-channel field effect transistors (pFETs), such pFETs for one embodiment may be activated after a threshold voltage (Vtp) due to forward biasing of p-type well(s) 512 is developed. Using such pFETs for one embodiment may then help allow pull-up transistors 552 and 562 to boost bias of p-type well(s) 512 to the second state faster.

To return p-type well(s) 512 to the first state, pull-down transistor 542 may be activated in response to a deasserted activate signal and pull-up transistor 552 may be deactivated in response to the deasserted activate signal to decrease a voltage level of p-type well(s) 512. For one embodiment where return of p-type well(s) 512 to the first state is less time critical, pull-down transistor 542 may be sized smaller to help reduce or minimize direct current (DC) power consumption by circuitry 500.

### EXAMPLE TIMING DIAGRAM

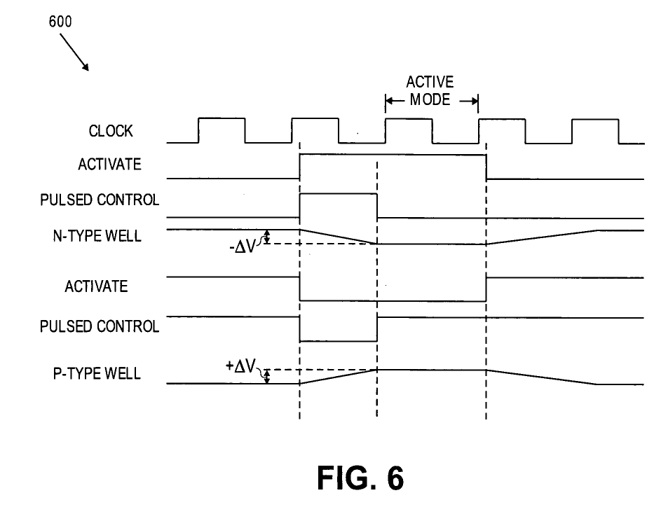

FIG. 6 illustrates, for one embodiment, an example, although relatively crude, timing diagram 600 for the example circuitry of FIGS. 4 and 5.

As illustrated in FIG. 6, an active-high activate signal may be asserted in response to a clock transition one clock cycle prior to placement of circuitry 410 of FIG. 4 in an active mode. An active-high pulsed control signal may be generated in response to assertion of the activate signal to help boost bias of one or more n-type wells 412 from a first state at a first voltage level to a second state at a second, decreased voltage level. In response to a clock transition upon placement of circuitry 410 out of the active mode into another mode, such as a standby mode for example, the activate signal may be deasserted to return n-type well(s) 412 to the first state.

Also as illustrated in FIG. 6, an active-low activate signal may be asserted in response to a clock transition one clock cycle prior to placement of circuitry 510 of FIG. 5 in an active mode. An active-low pulsed control signal may be generated in response to assertion of the activate signal to help boost bias of one or more p-type wells 512 from a first state at a first voltage level to a second state at a second, increased voltage level. In response to a clock transition upon placement of circuitry 51 0 out of the active mode into another mode, such as a standby mode for example, the activate signal may be deasserted to return p-type well(s) 512 to the first state.

### EXAMPLE SYSTEM

Dynamic bias circuitry 120 and boost circuitry 130 may dynamically bias one or more wells of a substrate with a bias boost for any suitable circuitry including such well(s) on any suitable integrated circuit. Although dynamic bias circuitry 120 and boost circuitry 130 are described and illustrated for one embodiment as dynamically biasing one or more wells in the same integrated circuit on which dynamic bias circuitry 120 and boost circuitry 130 reside, dynamic bias circuitry 120 and/or boost circuitry 130 for one embodiment may reside on an integrated circuit separate from an integrated circuit having one or wells that are to be biased using dynamic bias circuitry 120 and boost circuitry 130.

Dynamic bias circuitry 120 and boost circuitry 130 for one embodiment may be used to dynamically bias one or more wells with a bias boost for one or more memory cells of any suitable memory, such as a static random access memory (SRAM) for example. Dynamic bias circuitry 120 and boost circuitry 130 for one embodiment may be activated to bias one or more wells of a substrate from a first state to a second state with a bias boost to access one or more memory cells including such well(s) and to return one or more wells of the substrate to the first state after one or more memory cells have been accessed. Dynamic bias circuitry 120 and boost circuitry 130 for one embodiment may be activated to bias one or more wells with a bias boost in response to any suitable select signal. used to select one or more memory cells for access.

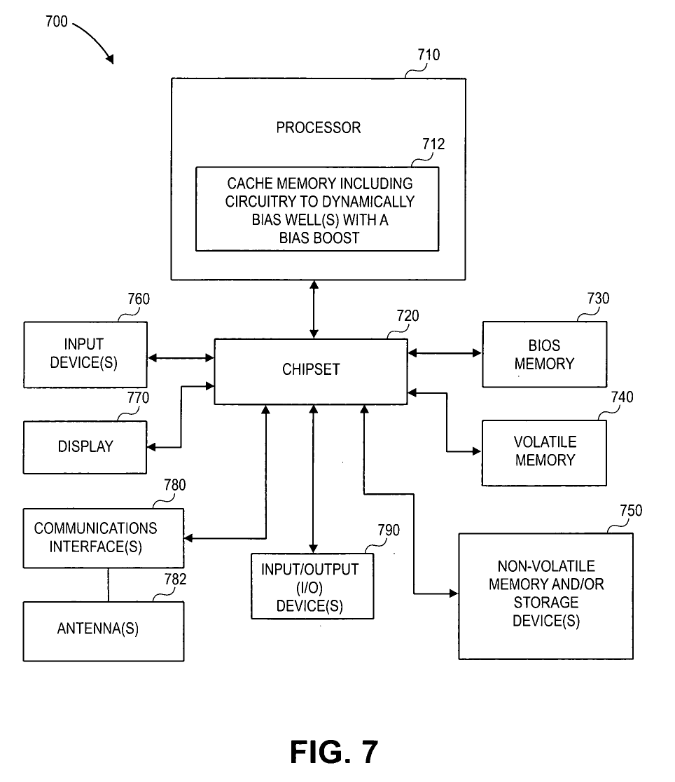

Such memory may be used for any suitable purpose in any suitable system such as, for example, for cache memory 712 in a processor 710 of a system 700 of FIG. 7.

As illustrated in FIG. 7, system 700 for one embodiment may comprise processor 710 having cache memory 712 including dynamic bias circuitry 120 and boost circuitry 130 to dynamically bias one or more wells of a substrate with a bias boost. Although illustrated as a part of processor 710 for one embodiment, cache memory 712 for another embodiment may be separate from processor 710. System 700 for another embodiment may include multiple processors one or more of which may have cache memory similar to cache memory 712.

System 700 for one embodiment may also include a chipset 720 coupled to processor 710, a basic input/output system (BIOS) memory 730 coupled to chipset 720, volatile memory 740 coupled to chipset 720, non-volatile memory and/or storage device(s) 750 coupled to chipset 720, one or more input devices 760 coupled to chipset 720, a display 770 coupled to chipset 720, one or more communications interfaces 780 coupled to chipset 720, and/or one or more other input/output (I/O) devices 790 coupled to chipset 720.

Chipset 720 for one embodiment may include any suitable interface controllers to provide for any suitable communications link to processor 710 and/or to any suitable device or component in communication with chipset 720.

Chipset 720 for one embodiment may include a firmware controller to provide an interface to BIOS memory 730. BIOS memory 730 may be used to store any suitable system and/or video BIOS software for system 700. BIOS memory 730 may include any suitable non-volatile memory, such as a suitable flash memory for example. BIOS memory 730 for one embodiment may alternatively be included in chipset 720.

Chipset 720 for one embodiment may include one or more memory controllers to provide an interface to volatile memory 740. Volatile memory 740 may be used to load and store data and/or instructions, for example, for system 700. Volatile memory 740 may include any suitable volatile memory, such as suitable dynamic random access memory (DRAM) for example. Processor 710 for one embodiment may use cache memory 712 to store data and/or instructions stored or to be stored in volatile memory 740, for example, for faster access to such data and/or instructions.

Chipset 720 for one embodiment may include a graphics controller to provide an interface to display 770. Display 770 may include any suitable display, such as a cathode ray tube (CRT) or a liquid crystal display (LCD) for example. The graphics controller for one embodiment may alternatively be external to chipset 720.

Chipset 720 for one embodiment may include one or more input/output (I/O) controllers to provide an interface to non-volatile memory and/or storage device(s) 750, input device(s) 760, communications interface(s) 780, and/or I/O devices 790.

Non-volatile memory and/or storage device(s) 750 may be used to store data and/or instructions, for example. Non-volatile memory and/or storage device(s) 750 may include any suitable non-volatile memory, such as flash memory for example, and/or may include any suitable non-volatile storage device(s), such as one or more hard disk drives (HDDs), one or more compact disc (CD) drives, and/or one or more digital versatile disc (DVD) drives for example.

Input device(s) 760 may include any suitable input device(s), such as a keyboard, a mouse, and/or any other suitable cursor control device.

Communications interface(s) 780 may provide an interface for system 700 to communicate over one or more networks and/or with any other suitable device. Communications interface(s) 780 may include any suitable hardware and/or firmware. Communications interface(s) 780 for one embodiment may include, for example, a network adapter, a wireless network adapter, a telephone modem, and/or a wireless modem. For wireless communications, communications interface(s) 780 for one embodiment may use one or more antennas 782.

I/O device(s) 790 may include any suitable I/O device(s) such as, for example, an audio device to help convert sound into corresponding digital signals and/or to help convert digital signals into corresponding sound, a camera, a camcorder, a printer, and/or a scanner.

Although described as residing in chipset 720, one or more controllers of chipset 720 may be integrated with processor 710, allowing processor 710 to communicate with one or more devices or components directly. As one example, one or more memory controllers for one embodiment may be integrated with processor 710, allowing processor 710 to communicate with volatile memory 740 directly.

In the foregoing description, example embodiments have been described. Various modifications and changes may be made to such embodiments without departing from the scope of the appended claims. The description and drawings are, accordingly, to be regarded in an illustrative rather than a restrictive sense.

What is claimed is:

1. An apparatus comprising:
first circuitry to bias one or more wells of a substrate from a first state to a second state; and
second circuitry to boost bias by the first circuitry of one or more wells of the substrate to the second state.

2. The apparatus of claim 1, wherein the first circuitry has a programmable bias strength.

3. The apparatus of claim 1, wherein the second circuitry has a programmable boost strength.

4. The apparatus of claim 1, wherein the first circuitry includes one or more transistors to couple one or more wells to a node.

5. The apparatus of claim 1, wherein the second circuitry includes one or more transistors to couple one or more wells to a node.

6. The apparatus of claim 5, wherein the second circuitry includes a pulse generator to generate one or more pulsed control signals to activate one or more transistors.

7. The apparatus of claim 6, wherein the pulse generator is programmable to set a width of a pulsed control signal.

8. The apparatus of claim 1, wherein the first circuitry includes a variable resistor coupled between one or more wells and a node.

9. The apparatus of claim 1, wherein the first circuitry is to decrease a voltage level of one or more n-type wells.

10. The apparatus of claim 1, wherein the first circuitry is to increase a voltage level of one or more p-type wells.

11. The apparatus of claim 1, wherein the first circuitry is to bias one or more wells of the substrate to the second state for an active mode and is to return one or more wells of the substrate to the first state for another mode.

12. A method comprising:
activating circuitry to bias one or more wells of a substrate from a first state to a second state; and
boosting bias by the circuitry of one or more wells of the substrate to the second state.

13. The method of claim 12, comprising programming a strength at which one or more wells are to be biased.

14. The method of claim 12, comprising programming a strength at which bias is to be boosted.

15. The method of claim 12, wherein boosting bias includes generating one or more pulsed control signals to activate one or more transistors to couple one or more wells to a node.

16. The method of claim 12, comprising deactivating circuitry to return one or more wells of the substrate to the first state.

17. A system comprising:
volatile memory; and
a processor having a cache memory, the cache memory including first circuitry to bias one or more wells of a substrate from a first state to a second state and second circuitry to boost bias by the first circuitry of one or more wells of the substrate to the second state.

18. The system of claim 17, wherein the first circuitry has a programmable bias strength.

19. The system of claim 17, wherein the second circuitry has a programmable boost strength.

20. The system of claim 17, wherein the second circuitry includes one or more transistors to couple one or more wells to a node and includes a pulse generator to generate one or more pulsed control signals to activate one or more transistors.

21. The system of claim 17, wherein the first circuitry is to bias one or more wells of the substrate to the second state to access one or more memory cells of the cache memory and is to return one or more wells of the substrate to the first state after one or more memory cells of the cache memory have been accessed.
